(19) United States
(12) Patent Application Publication
(10) Pub. No.: US 2026/0259354 A1
(43) Pub. Date: Sep. 3, 2026

(54) BIOMIMETIC TRANSPARENT NANOPLASMONIC MESHES BY REVERSE-NANOIMPRINT LITHOGRAPHY

(71) Applicant: VIRGINIA TECH INTELLECTUAL PROPERTIES, INC., Blacksburg, VA (US)

(72) Inventors: Aditya Garg, Blacksburg, VA (US); Wei Zhou, Blacksburg, VA (US); Elieser Mejia, Hanover, MD (US)

(21) Appl. No.: 18/867,989

(22) PCT Filed: Mar. 24, 2023
(86) PCT No.: PCT/US2023/064935

§ 371 Date: Nov. 21, 2024

Related U.S. Application Data
(60) Provisional application No. 63/365,227, filed on May 24, 2022.

(51) Int. Cl. G02B 5/00; C23C 14/02; C23C 14/04; C23C 14/10; C23C 14/20; C23C 14/28; G01N 21/65; G03F 7/00; H01Q 1/38

(52) U.S. Cl. CPC G02B 5/008; C23C 14/021; C23C 14/046; C23C 14/10; C23C 14/20; C23C 14/28; G01N 21/658; G03F 7/0002; G03F 7/0005; H01Q 1/38

(57) ABSTRACT

A reverse nanoimprint lithography approach is described to create biomimetic transparent nanoplasmonic microporous mesh (BTNMM) devices, nanolaminated plasmonic nanoantenna (NLPNA) arrays, and related structures. The NLPNAs can be formed on a range of different surfaces and structures, including flexible membranes, flexible polymeric sheets, flexible polymeric meshes, polymeric meshes, membranes, fabricated structures including electrodes, coated glass, and other surfaces. One example method includes forming a nanowell array, transferring the nanowell array to a surface using reverse nanoimprint lithography, etching the nanowell array to form a nanohole array comprising nanoholes that expose openings on the surface, depositing alternating metal and insulating layers into the nanoholes and onto the openings on the surface, to form a nanoantenna array on the surface, and dissolving the nanohole array.

### CROSS-REFERENCE TO RELATED APPLICATIONS

This application claims the benefit of and priority to U.S. Provisional Application No. 63/365,227, filed May 24, 2022, titled “Biomimetic Transparent Nanoplasmonic Meshes by Reverse-Nanoimprint Lithography,” the entire disclosure of which is hereby incorporated herein by reference.

### STATEMENT REGARDING FEDERALLY SPONSORED RESEARCH OR DEVELOPMENT

This invention was made with government support under Grant Nos. OISE-1545756, CBET-2029911, CBET-2231807, and DMR-2139317 awarded by the National Science Foundation. This invention was also made with government support under Grant No. FA9550-18-1-0328 awarded by the Air Force Office of Scientific Research. The government has certain rights in the invention.

### BACKGROUND

Photonics is a branch of optics that involves the generation, detection, and manipulation of light in the form of photons. The field of plasmonics is related to the detection and manipulation of optical signals using metal-dielectric interfaces in the nanometer scale. Following the trend of photonics, the field of plasmonics seeks to miniaturize the optical devices used for the detection and manipulation of optical signals. Plasmonics can be applied to a range of different applications finds uses in optical sensing, microscopy, optical communications, and bio-photonics, among other fields.

### SUMMARY

A reverse nanoimprint lithography approach is described to create biomimetic transparent nanoplasmonic microporous mesh (BTNMM) devices, nanolaminated plasmonic nanoantenna (NLPNA) arrays, and related plasmonic device structures. The NLPNAs can be formed on a range of different surfaces and structures, including flexible membranes, flexible polymeric sheets, flexible polymeric meshes, polymeric meshes, membranes, fabricated structures including electrodes, coated glass, and other surfaces based on the reverse nanoimprint lithography approach.

An example method includes forming a nanowell array, transferring the nanowell array to a surface using reverse nanoimprint lithography, etching the nanowell array to form a nanohole array comprising nanoholes that expose openings on the surface, depositing alternating metal and insulating layers into the nanoholes and onto the openings on the surface, to form a nanoantenna array on the surface, and dissolving the nanohole array.

Forming the nanowell array can include forming a nanowell array master, forming a nanopillar array mold using the nanowell array master, and forming the nanowell array using the nanopillar array mold. More particularly, forming the nanowell array can include forming a nanowell array master in silicon, forming a nanopillar array mold from perfluoropolyether (PFPE) using the nanowell array master, and forming the nanowell array from poly(methyl methacrylate) (PMMA) using the nanowell array master. Forming the nanowell array can include preparing a solution of PMMA in a solvent, spin coating the solution of PMMA over the nanopillar array mold, and heating the solution of PMMA to evaporate the solvent.

The nanowell array can be transferred onto a range of surfaces and structures. Example surfaces or structures include the top surface of a microwell mesh having a plurality of microwells, the top surfaces of micropillars in a micropillar array, the top surface of a coated glass, an array of interdigitated electrodes on a microwell mesh, and other surfaces. The microwell mesh can be embodied as a transparent, polymeric microwell mesh.

An example method of manufacture of a BTNMM device includes forming a nanowell array master in a silicon substrate, forming a hydrophobic nanopillar array mold from hydrophobic perfluoropolyether (PFPE) using the nanowell array master, forming a solvent-soluble nanowell array from poly(methyl methacrylate) (PMMA) using the hydrophobic nanopillar array mold, forming a microwell mesh over a carrier substrate, transferring the nanowell array to a surface of the microwell mesh using reverse nanoimprint lithography, etching the nanowell array to form a nanohole array comprising nanoholes that expose openings on the surface of the microwell mesh, depositing alternating metal and insulating layers over the nanohole array and onto the openings on the surface of the microwell mesh, to form a nanoantenna array on the surface, dissolving the nanowell array, and releasing the microwell mesh and the nanoantenna array from the carrier substrate.

A number of BTNMM devices and NLPNA arrays are also described. An example BTNMM device includes a flexible, transparent microwell mesh having a plurality of microwells, and a nanoantenna array on a surface of the microwell mesh. Each nanoantenna in the nanoantenna array includes alternating metal and insulating layers of metal and an insulator. An example NLPNA array includes micropillars and nanoantenna arrays on the top surfaces of the micropillars.

### BRIEF DESCRIPTION OF THE DRAWINGS

Many aspects of the present disclosure can be better understood with reference to the following drawings. The components in the drawings are not necessarily drawn to scale, with emphasis instead being placed upon clearly illustrating the principles of the disclosure. In the drawings, like reference numerals designate corresponding parts throughout the several views.

FIG. 1A illustrates an example biomimetic transparent nanoplasmonic microporous mesh (BTNMM) according to various aspects of the embodiments.

FIG. 1B illustrates an example of nanolaminated plasmonic nanoantenna (NLPNA) arrays formed on micropillar structures according to various aspects of the embodiments.

FIG. 1C illustrates an example nanolaminated plasmonic nanoantenna according to various aspects of the embodiments.

FIG. 2 illustrates example shapes and geometries for micropores or microwells and micropillars used in BTNNMs and NLPNA arrays according to various aspects of the embodiments.

FIG. 3 illustrates an example method of fabricating BTNNMs and NLPNA arrays according to various aspects of the embodiments.

FIG. 4A illustrates a cross-sectional view of a representative nanopillar array mold according to various aspects of the embodiments.

FIG. 4B illustrates a cross-sectional view of a poly(methyl methacrylate) (PMMA) solution being spin coated over a nanopillar array mold according to various aspects of the embodiments.

FIG. 4C illustrates a cross-sectional view of a nanowell array over a nanopillar array mold according to various aspects of the embodiments.

FIG. 4D illustrates a cross-sectional view of a microwell mesh scaffold formed over a substrate or carrier according to various aspects of the embodiments.

FIG. 4E illustrates a cross-sectional view of a nanowell array being transferred to a microwell mesh scaffold according to various aspects of the embodiments.

FIG. 4F illustrates a cross-sectional view of a nanowell array transferred to a microwell mesh scaffold according to various aspects of the embodiments.

FIG. 4G illustrates a cross-sectional view of nanoholes formed though a nanowell array over a microwell mesh scaffold according to various aspects of the embodiments.

FIG. 4H illustrates a cross-sectional view of nanoantennas formed in nanoholes according to various aspects of the embodiments.

FIG. 4I illustrates a cross-sectional view of nanoantennas formed on a microwell mesh scaffold with a supporting substrate or carrier according to various aspects of the embodiments.

FIG. 4J illustrates a cross-sectional view of nanoantennas formed on a microwell mesh scaffold according to various aspects of the embodiments.

### DETAILED DESCRIPTION

Multicellular systems, such as microbial biofilms and cancerous tumors, feature complex biological activities coordinated by cellular interactions mediated via different signaling and regulatory pathways, which are intrinsically heterogeneous, dynamic, and adaptive. It is important to capture the holistic, system-level spatiotemporal picture of such multicellular systems to understand complex and dynamically evolving biological activities and to determine effective therapeutic intervention methods. However, due to their invasiveness or their inability to interface with native cellular networks, standard bioanalysis methods do not allow in situ spatiotemporal biochemical monitoring of multicellular systems to capture holistic spatiotemporal pictures of systems-level biology.

For example, it is known that that microorganisms in biofilms can better resist antibiotic exposure or host immune response via multiple mechanisms, including EPS diffusion barrier, metabolic dormancy, antibiotic resistance gene transfer, quorum sensing, and polymicrobial synergism. Unfortunately, there are few methods for monitoring spatiotemporal biofilm activities that allow the investigation of how these different survival mechanisms interplay to affect system-level biofilm responses. Standard chemical bioanalysis methods in microbiology studies can be categorized as ex situ (off-site) or in situ (on-site). Among ex situ bioanalysis techniques, targeted molecular detection methods, including polymerase chain reaction (PCR) based tests and immunoassays, are the traditional tools used to identify genetic or proteomic markers for known microbes. Non-targeted molecular profiling methods based on mass spectrometry (MS) or nuclear magnetic resonance (NMR) spectroscopy are powerful discovery-based ex situ metabolomics tools used to characterize the metabolic response of living systems to environmental, pathophysiological, or genetic perturbations. Despite their strength in analytical quantification, standard ex situ bioanalysis methods are destructive and cannot resolve the spatiotemporal activities of multicellular systems to study genotypic/phenotypic variations between subpopulations.

Standard in situ bioanalyses for biofilms rely on fluorescence microscopy imaging of probe-labeled cellular components, which can measure spatial distributions of microbes in biofilms. Unfortunately, such label-based imaging approaches are invasive to living cells due to staining and cannot be used to map longitudinal biochemical activities (e.g., metabolic responses) in living biofilms. Recently, biosensing techniques, which exploit surface-functionalized receptors to detect targeted biomarkers, have emerged for in situ biochemical monitoring of living systems. However, existing biosensors cannot perform holistic non-targeted molecular profiling for discovery-based biological studies. Further, typical biosensing systems based on rigid planar substrates are unsuitable for interfacing with three-dimensional microbial biofilm networks in clinically relevant situations (e.g., wound or implant surfaces).

As a nano-enabled ultrasensitive vibrational biosensing-bioanalysis technique, surface-enhanced Raman spectroscopy (SERS) enjoys the advantages of noninvasive measurements, minimal sample preparation, and no water background interference. Uniquely, SERS can operate either in targeted or non-targeted modalities. Targeted SERS uses surface-functionalized reporter molecules to detect specific analytes (e.g., proteins, nucleic acids, etc.) or physical properties of the local environment (e.g., pH, temperature). Although targeted SERS assays in the sandwich immunoassay format are not suitable for the spatiotemporal analysis of living biosystems due to the need for a secondary capture probe, targeted SERS assays where the vibrational frequency of SERS labels change in response to the target molecules or changes in environmental parameters can be employed. Non-targeted SERS measure the fingerprint profiles of molecule ensembles in SERS hotspots and require multivariate analysis via methods such as machine learning approaches. For the in situ biochemical analysis of living multicellular systems, it is highly desirable to perform multimodal spatiotemporal SERS measurements in both non-targeted and targeted modalities as they can provide complementary information. For example, bacterial biofilm development processes are spatiotemporally coupled with changes in local pH and biomolecule (e.g., intercellular signaling molecules, nutrients, and waste products) concentrations. These processes generate a heterogeneous distribution of bacterial subpopulations within the biofilms.

Since specific subpopulations in the microbial community serve defined roles, such as dormant cells that can withstand antibiotic attacks, resolving the spatiotemporal evolution of pH and different biochemical components can potentially assist therapeutic intervention. However, implementing multimodal spatiotemporal SERS bioanalysis in both targeted and non-targeted modalities remains a formidable challenge primarily because surface-functionalized SERS substrates provide weak label-free signals from target molecules due to the spatial competition of occupation between the Raman reporter molecules and the non-targeted analyte molecules at the SERS hotspots.

Defined by their spatial hotspot arrangement, SERS devices are characterized as unbound or surface-bound. Unbound SERS devices based upon discrete plasmonic nanoparticles or nanoantennas can intimately interface with cells, but often suffer from poor spatiotemporal reproducibility because of the uncontrolled diffusion, aggregation, and distribution of the randomly organized nanoparticles. Surface-bound SERS devices, often created by top-down nanofabrication, carry mechanically stabilized plasmonic hotspots in uniform arrays for reliable spatiotemporal measurements. To date, surface-bound SERS devices typically exhibit a continuous planar form since conventional nanofabrication processes, such as electron beam lithography (EBL) and deep-ultraviolet lithography (DUVL), rely on planar spin-coating and flat substrate lithography. However, continuous planar SERS devices elicit a poor nano-bio interface with native cellular networks due to the mismatch in their mechanical, topological, and permeable properties.

To help address a range of issues including those described above, the embodiments described herein are directed to new ways of manufacturing dense and uniform hotspot arrays for in situ spatiotemporal SERS bioanalysis. Plasmonic nanoantenna arrays based on metal nanostructures can support surface plasmon resonances. The plasmon resonances enhance light-matter interactions at the nanoscale for bio-interfaced spectroscopy, sensing, actuation, and other uses. For example, plasmonic nanoantennas can enable SERS for the sensitive detection of biochemical analytes and in-situ molecular profiling of living biological systems. Plasmonic nanoantennas modified with specific receptors can also achieve refractive index (RI) sensing of target biomolecules in biological environments. Plasmonic nanoantennas can also serve as nanolocalized photothermal heat sources, to induce cell membrane optoporation for drug delivery and the excitation of neurons. Thus, the development of microporous mesh plasmonic devices offers new opportunities for bio-interfaced optical sensing and actuation applications, among others.

In the field of plasmonic nanoantenna arrays, flexible, mesh-like microporous devices offer biocompatibility advantages for interfacing with cell networks and tissues, biomedical sensing, biomedical actuation, and other applications. Flexible microporous devices having relatively low elastic moduli and high permeability to nutrients and oxygen are better candidates for biocompatibility. Many microporous mesh devices employ arrays of electrical components, including microelectrodes and nanoscale transistors. Such electrical mesh devices can serve as inflammation-free epidermal sensors for long-term health monitoring, sensor-array scaffolds for in-vitro drug response monitoring in cell culture models, and minimally invasive brain probes for in-vivo electrical recording in animals. As compared to electrical mesh devices, there has been relatively little work on optical mesh devices, such as optical mesh devices based on dense plasmonic nanoantenna arrays for bio-interfacing applications.

Microporous mesh plasmonic devices have the potential to combine the biocompatibility of microporous polymeric meshes with the capabilities of plasmonic nanostructures. Microporous mesh plasmonic devices can enhance light-matter interactions, at the nanoscale level, for bio-interfaced optical sensing and actuation, among other useful applications. It has been challenging, however, to integrate uniformly structured plasmonic devices at scale. It has also been challenging to fabricate uniformly structured plasmonic devices into microporous meshes at scale. The scalable integration of dense and uniformly structured plasmonic hotspot arrays with microporous polymeric meshes is challenging, in part, due to the processing incompatibility of conventional nanofabrication methods with flexible microporous substrates. Plasmonic devices have been formed using top-down fabrication methods, such as EBL, focused ion beam (FIB), DUVL, laser-direct-writing (LDW), and nanoimprint lithography (NIL), but those techniques are subject to the limitations described above. Despite research efforts, the existing methods of forming plasmonic devices face challenges and drawbacks, particularly as to scalable nanofabrication methods compatible with flexible microporous substrates.

A high-throughput reverse nanoimprint lithography (RNIL) approach is described to create biomimetic transparent nanoplasmonic microporous mesh (BTNMM) devices, nanolaminated plasmonic nanoantenna (NLPNA) arrays, and related structures. The NLPNAs can be formed on a range of different surfaces and structures, including flexible membranes, flexible polymeric sheets, flexible polymeric meshes, polymeric meshes, membranes, fabricated structures including electrodes, coated glass, and other surfaces. The NLPNAs can also be formed on textiles and other flexible structures or materials in some cases.

Example BTNMM devices include thin flexible microporous structures and arrays of nanoantennas for spatiotemporal multimodal SERS measurements at bio-interfaces. The BTNMMs, supporting the uniformly-distributed nanoantenna SERS hotspots, can simultaneously enable spatiotemporal multimodal SERS measurements for targeted pH sensing and non-targeted molecular detection to resolve the diffusion dynamics for pH, adenine, and Rhodamine 6G (R6G) molecules in agarose gel, among other applications. The BTNMMs can act as multifunctional bio-interfaced SERS sensors to conduct in situ spatiotemporal pH mapping and molecular profiling of Escherichia coli biofilms. The multimodal SERS capability, transport permeability, and biomechanical compatibility of the BTNMMs open new avenues for bio-interfaced multifunctional sensing applications both in vitro and in vivo applications.

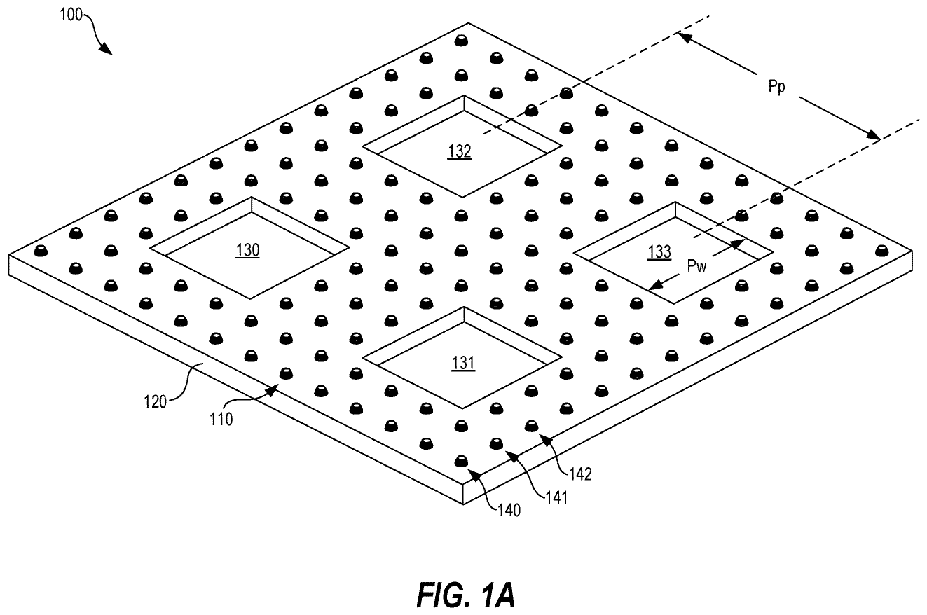

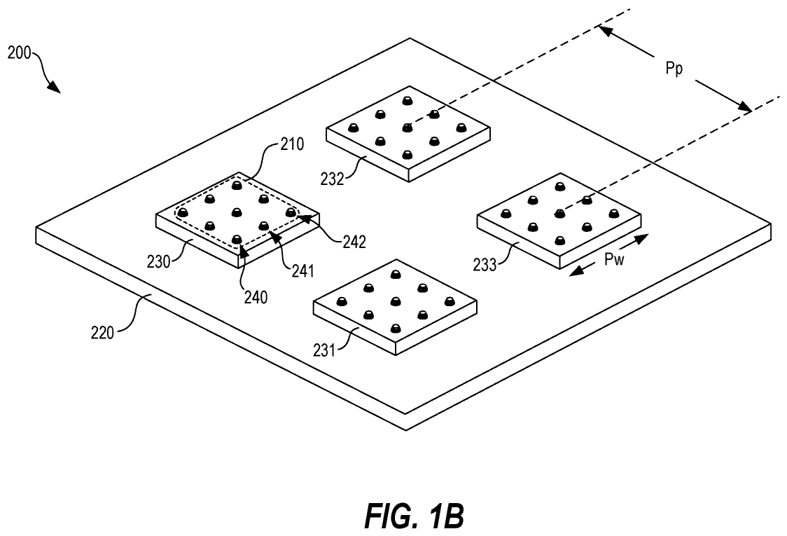

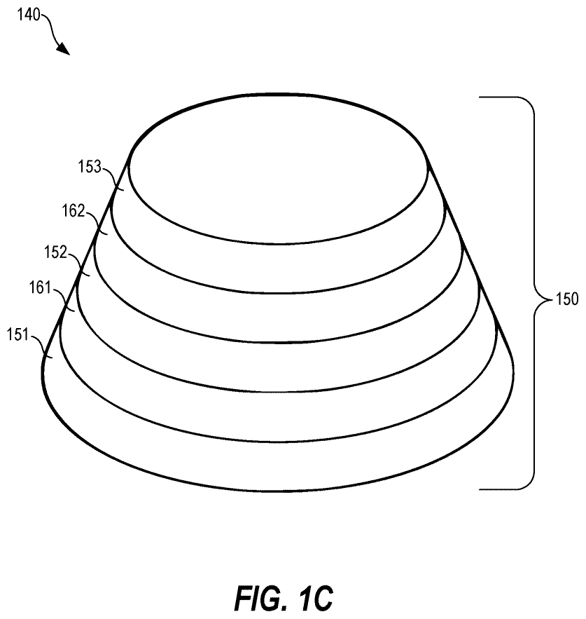

Turning to the drawings, FIG. 1A illustrates an example BTNMM 100 according to certain aspects of the embodiments. The BTNMM 100 is provided as a representative example of a BTNNM according to the concepts described herein. The BTNMM 100 is not drawn to any particular scale or size, and the embodiments are not limited to any particular type or size of BTNNM. In practice, the BTNMM 100 can be larger, smaller, formed in different shapes, and have different structural characteristics as compared to that shown. The BTNMM 100 includes a nanoantenna array 110 and a flexible scaffold 120 (also “scaffold 120”). The nanoantenna array 110 is an example of an NLPNA array, as described herein.

The scaffold 120 can be formed from a thin, flexible, and biocompatible material. The scaffold 120 can be embodied as a flexible membrane, flexible polymeric sheet, flexible polymeric mesh, or other surface or structure. Thus, the scaffold 120 can conform to various surfaces, including curved surfaces, and the BTNMM 100 can be placed in conformal contact with skin in some applications. The scaffold layer 120 includes a number of wells, pores, openings, or apertures, such as the micropores 130-133. The micropores 130-133 extend through the scaffold 120 to permit fluids, cells, and other materials to extend into and through the micropores 130-133, for analysis using the BTNMM 100.

The micropores 130-133 can be formed in a range of suitable sizes and shapes. The micropores 130-133 are shown as square pores in FIG. 1A, although other shapes can be relied upon. Other pore shapes and geometries are described below with reference to FIG. 1C. The micropores 130-133 can be sized to have a pore width “Pw” in the micrometer range, such as between 1-100 μm, including all the widths between 1 μm and 100 μm in increments of 1 μm (e.g., 1 μm, 2 μm, 3 μm, . . . 99 μm, and 100 μm), although smaller and larger pore sizes can be used in some cases. As measured from the centers of any two micropores, the micropores 130-133 can be spaced at a periodicity or pitch of “Pp” between 3-1000 μm, including all the pitch spacings between 3 μm and 1000 μm in increments of 1 μm, although other pitches be used.

The BTNMM 100 can omit or lack the micropores 130-133 in some cases. In that case, the resulting structure may be referenced as a nanolaminated plasmonic nanoantenna (NLPNA) array. That is, the scaffold 120 can omit the micropores 130-133, and the nanoantenna array 110 can be formed on or over the entire top surface of the scaffold 120. Such an NLPNA array (i.e., without the micropores 130-133) is one example of a flexible NLPNA array according to aspects of the embodiments.

The nanoantenna array 110 includes an NLPNA array. As shown in FIG. 1A, the nanoantenna array 110 includes a number of uniformly-spaced nanoantennas 140-142, among others. Each of the nanoantennas 140-142 is formed by a materials stack. The materials stack includes a multi-layered metal-insulator-metal stack of materials, which is described in additional detail below with reference to FIG. 1C. The nanoantenna array 110 is illustrated on the scaffold 120 in FIG. 1A, but the nanoantenna array 110 can be formed on a range of other surfaces and structures according to the embodiments.

FIG. 1B illustrates an example of an NLPNA micropillar array 200 according to various aspects of the embodiments. The NLPNA micropillar array 200 is provided as a representative example of NLPNA arrays formed over micropillars. The NLPNA micropillar array 200 is not drawn to any particular scale or size, and the embodiments are not limited to any particular type or size of NLPNA micropillar arrays. In practice, the NLPNA micropillar array 200 can be larger, smaller, formed in different shapes, and have different structural characteristics as compared to that shown. The NLPNA micropillar array 200 includes nanoantenna arrays on micropillars 230-233. The micropillars 230-233 are supported over a supporting substrate or carrier 220. A nanoantenna array 210 is shown on the micropillar 230, and similar nanoantenna arrays are positioned on or over the other micropillars 231-233.

The micropillars 230-233 can be formed as polymeric pillars in one example, although a range of materials can be used to form the micropillars 230-233. Fluids, cells, and other materials can extend between and among the micropillars 230-233 for analysis using the NLPNA micropillar array 200.

The micropillars 230-233 can be formed in a range of suitable sizes and shapes, as described below. The micropillars 230-233 are shown as square pillars in FIG. 1B, although other shapes can be relied upon. Other pillar shapes and geometries are described below with reference to FIG. 1C. The micropillars 230-233 can be sized to have a pillar width “Pw” in the micrometer range, such as between 1-100 μm, including all the widths between 1 μm and 100 μm in increments of 1 μm (e.g., 1 μm, 2 μm, 3 μm, . . . 99 μm, and 100 μm), although smaller and larger pore sizes can be used in some cases. As measured from the centers of any two micropillars, the micropillars 230-233 can be spaced at a periodicity or pitch of “Pp” between 3-1000 μm, including all the pitch spacings between 3 μm and 1000 μm in increments of 1 μm, although other pitches be used. The height of the micropillars 230-233 (i.e., as measured from the top surface of the substrate or carrier 220 to the top surface of the micropillars 230-233, can also range, such as between 200 nm-5 μm, although other heights can be relied upon.

The nanoantenna array 210 includes an NLPNA array. As shown in FIG. 1B, the nanoantenna array 210 includes a number of uniformly-spaced nanoantennas 240-242, among others. Each of the nanoantennas 240-242 is formed by a materials stack. The materials stack includes a multi-layered metal-insulator-metal stack of materials, which is described in additional detail below with reference to FIG. 1C. Similar nanoantenna arrays are positioned on or over the other micropillars 231-233.

FIG. 1C illustrates an example nanolaminated plasmonic nanoantenna 140 according to various aspects of the embodiments. The nanoantenna 140 is provided as a representative example and is not drawn to any particular scale or size, and the embodiments are not limited to any particular type or size of nanoantenna. In practice, the nanoantenna 140 can be larger, smaller, formed in different shapes, and have different structural characteristics as compared to that shown. The nanoantenna 140 is representative of a single nanoantenna among a larger array of nanoantenna in an NLPNA array.

The nanoantenna 140 is formed from a materials stack 150. The materials stack 150 includes a multi-layered metal-insulator-metal stack of materials. The materials stack 150 includes metal layers 151-153 and insulating layers 161 and 162. Particularly, from bottom to top, the materials stack 150 includes the metal layer 151, the insulating layer 161 over the metal layer 151, the metal layer 152 over the insulating layer 161, the insulating layer 162 over the metal layer 152, and the metal layer 153 over the insulating layer 162. The metal and insulating layers can be formed as thin films by electron-beam physical vapor deposition (EBPVD) or other suitable materials deposition processing techniques. The nanoantenna 140 can also be formed with fewer or greater metal and insulating layers. As examples, arrays of nanoantenna can be formed having 1 metal layer (1ML and no insulating layers), 2 metal layers (2MLs), 3 metal layers (3MLs), 4 metal layers (4MLs), or more metal layers, with insulating layers separating the metal layers.

The metal layers 151-153 can be formed from gold (Au), silver (Ag), or copper (Cu) by EBPVD, although other metals and materials deposition techniques can be used in other cases. The metal layers 151-153 can be formed at a thickness between 15-35 nm, for example, including all thicknesses between 15 nm and 35 nm in increments of 1 nm, and other thicknesses can be relied upon in some cases. The metal layers 151-153 can also include thinner layers of titanium (Ti) between the Au, Ag, or Cu layers (i.e., on the top, the bottom, or both the top and bottom of the Au, Ag, or Cu layers) and the insulating layers 161 and 162 to help with adhesion of the metal and insulating layers. The layers of titanium can be between 0.5-0.9 nm in thickness, including thicknesses of 0.5 nm, 0.6 nm, 0.7 nm, 0.8 nm, or 0.9 nm, although other thicknesses can be used.

The insulating layers 161 and 162 can be formed from silicon dioxide (SiO₂) or titanium dioxide (TiO₂) by EBPVD, although other dielectric other insulators and materials deposition techniques can be used in other cases. The insulating layers 161 and 162 can be formed at a thickness between 5 -15 nm, for example, including thicknesses of 8 nm, 9 nm, 10 nm, 11 nm, 12 nm, although other thicknesses can be used. In one example, the insulating layers 161 and 162 can vary in thickness. For example, the insulating layer 161 can be 12 nm in thickness, and the insulating layer 162 can be 8 nm in thickness. The insulating layers 161 and 162 can also be formed to other thicknesses.

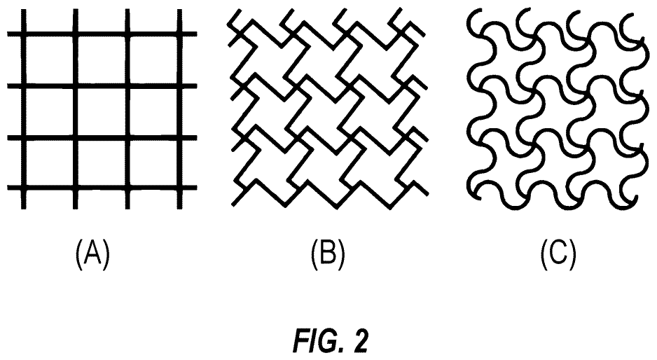

FIG. 2 illustrates example shapes and geometries for micropores or microwells and micropillars that can be relied upon among the embodiments. In (A), a square shape for micropores, microwells, and micropillars, similar to the micropores 130-133 in FIG. 1A and the micropillars 230-233 in FIG. 1B, is shown. Other four-sided shapes can be used, including rectangle and rhombus shapes. In practice, shapes with sharp corners can result in rounded corners or edges, due to the flexible nature of the materials from which the scaffolds or pillars are formed. The shapes of the micropores, microwells, and micropillars are not limited to four-sided shapes, however, and shapes other than four-sided shapes can be implemented. As examples, circular, oval, and other shapes of micropores, microwells, and micropillars can be used. Additionally, in (B), a fan shape with squared corners is shown as another shape for micropores, microwells, and micropillars according to the embodiments. In (C), a fan shape with rounded corners is shown. Other shapes can also be used, including “S,” “L,” serpentine, and other shapes.

Plasmonic devices have been formed using top-down fabrication methods, such as EBL, FIB, DUVL, LDW, and NIL techniques. However, the existing methods of plasmonic devices face a number of challenges, such as relatively low hotspot density, weak excitability of multipolar modes, and lack of scalable nanofabrication methods compatible with flexible microporous substrates. It has also been challenging to integrate uniformly structured plasmonic devices at scale and to fabricate uniformly structured plasmonic devices into microporous meshes at scale. The scalable integration of dense and uniformly structured plasmonic arrays with microporous polymeric meshes is challenging, in part, due to the processing incompatibility of conventional nanofabrication methods with flexible microporous substrates.

Below, new techniques are described to nanofabricate mechanically-stabilized NLPNA arrays, such as the BTNMM 100 and the NLPNA micropillar array 200. The approaches can be relied upon to form NLPNA arrays onto a range of surfaces or substrates, including flexible surfaces or substrates, such as flexible membranes, textiles, and scaffolds. The result is a flexible NLPNA array having a range of applications in plasmonics. Thus, new methods for the fabrication of biomimetic nanoplasmonics, biomimetic transparent nanoplasmonic meshes, and biomimetic transparent nanoplasmonic microporous meshes are described below.

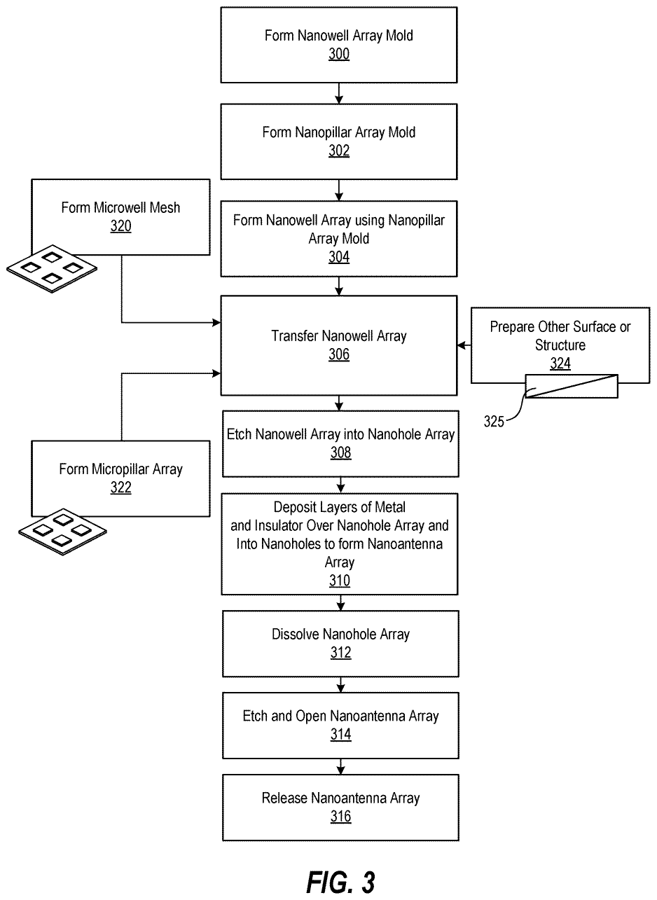

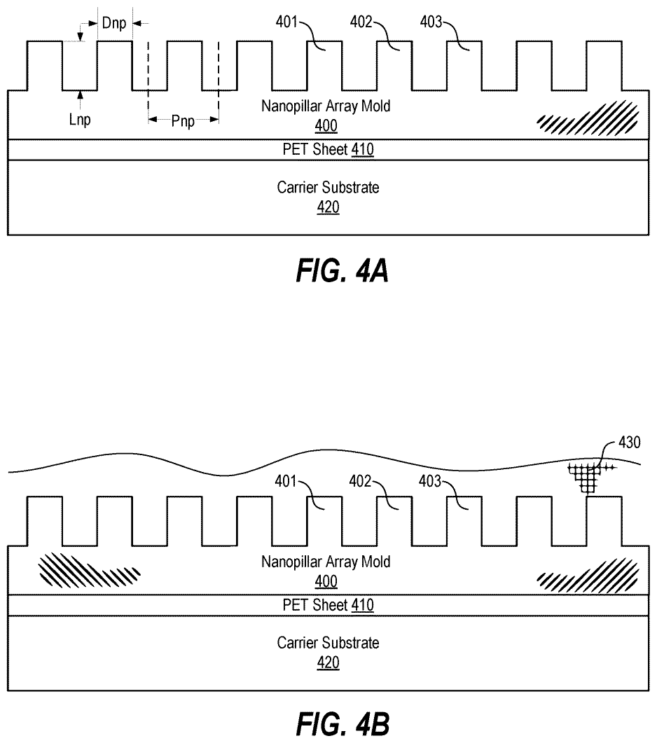

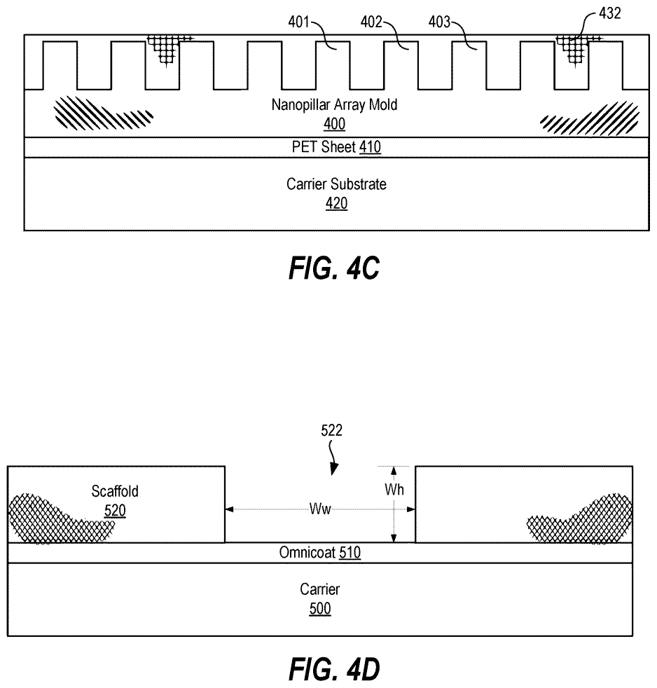

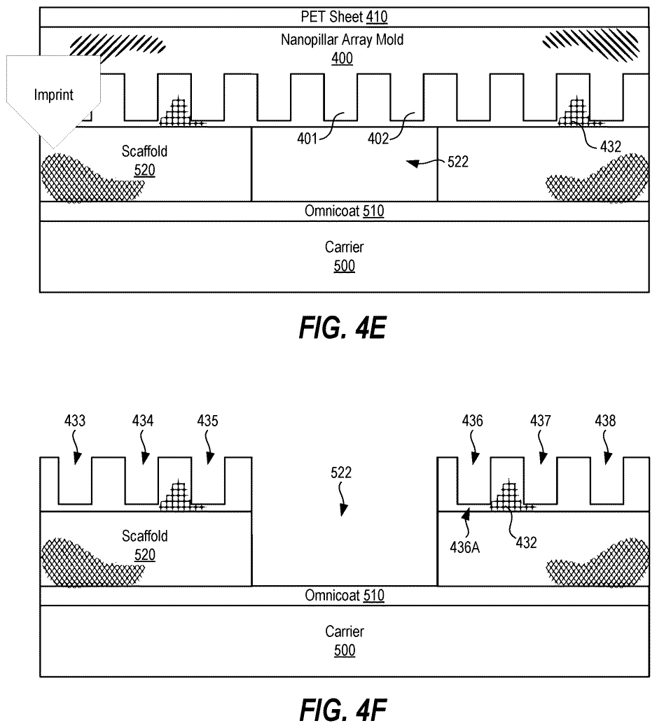

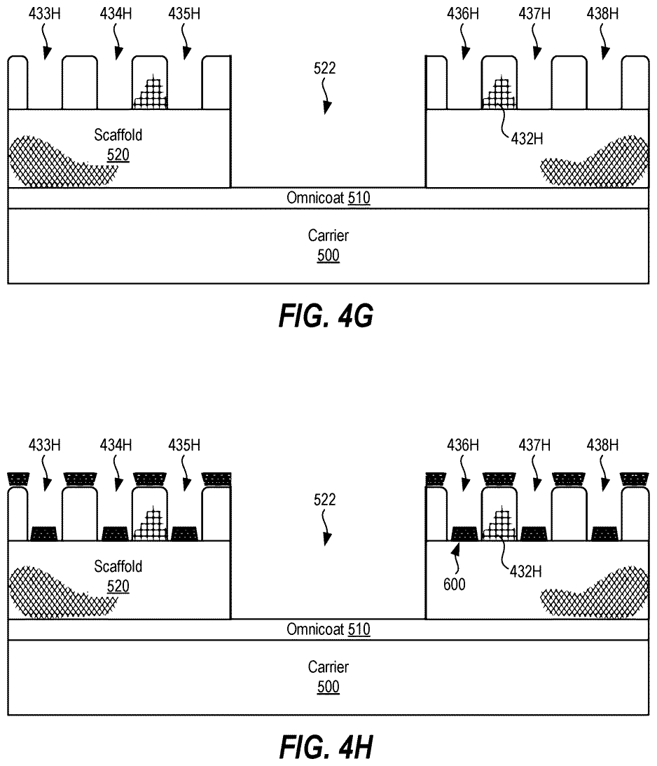

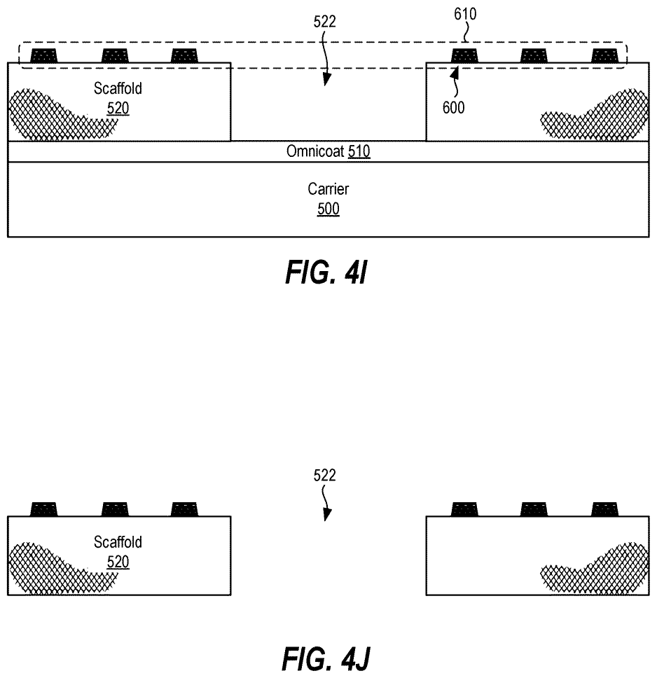

FIG. 3 illustrates an example method of fabricating BTNNMs and NLPNA arrays according to various aspects of the embodiments. The particular sequence of steps illustrated in FIG. 3 can vary as compared to that shown. For example, one or more of the steps can be rearranged in order, one or more of the steps can be omitted, and one or more additional steps can be added to the process shown. Additionally, two or more of the steps can be performed concurrently or, at least in part, at the same time. The steps identified in FIG. 3 are also described with reference to FIGS. 4A-4J. The illustrations in FIGS. 4A-4J are representative, and the concepts described herein can be applied to form BTNNMs and NLPNA arrays having different shapes, sizes, and other characteristics.

At step 300, the process includes forming a nanowell array master. The nanowell array master can be relied upon to form a nanopillar array mold at step 302. The nanowell array master can be formed using a silicon substrate, for example, or substrate of other material(s) as a mold. As one example, the nanowell array master can be formed by etching an array of wells into a silicon substrate. The nanowell array master can thus be embodied as a silicon substrate having a top surface, with an array of wells extending down into the silicon substrate from the top surface of the substrate. Each of the wells can be cylindrical in shape (i.e., having a circular bottom well surface), as one example, although wells having alternate shapes, such as wells having oval, square (or square with rounded corners), rectangular (or rectangular with rounded corners), or other shapes can be formed in some cases. The substrate can range in size, and typical wafer sizes can be used. Example wafer sizes include 100 mm, 125 mm, 150 mm, 200 mm, 300 mm, and 450 mm, and other sizes can be used.

The pitch or periodicity of the wells (i.e., as measured from a center of each well) in the substrate, in both directions of the array, can range among the embodiments. Example pitches or spacings between the wells (i.e., the periodicity of the wells) can range from 200 nm to 600 nm, for example, including all the pitch spacings between 200 nm to 600 nm in increments of 1 nm. Particular examples of pitches or spacings between the wells also include 250 mm, 300 mm, 350 mm, 400 mm, 450 mm, 500 mm, and 550 mm, although other spacings can be relied upon. Ultimately, the pitch spacing or periodicity of the wells in the nanowell array master will set the pitch spacing of the nanoantennas in the nanoantenna array formed in later steps.

The diameter of each well in the nanowell array master can range from 100 nm to 200 nm, including all the diameter spacings between 100 nm to 200 nm in increments of 1 nm. The depth of each well can range from 200 nm to 400 nm, including all the depth spacings between 200 nm to 400 nm in increments of 1 nm. In some cases, each well in the array of wells can have the same diameter and depth. However, in some cases, groups or sub-arrays of wells in the array can have different diameters, depths, and pitch spacings. The precision of the pitch, diameter, depth, and related spacings will depend on the precision of the etching or related technique used to form the wells, as would be understood by a person of skill.

At step 302, the method includes forming a nanopillar array mold using the nanowell array master from step 300. The nanopillar array mold can be a hydrophobic nanopillar array mold. As one example, the nanopillar array mold can be formed from a UV-curable hydrophobic perfluoropolyether (PFPE) using UV nanoimprint lithography. To form the mold, the top surface of the nanowell array master can be spin coated or drop dispensed with Fluorolink® MD700, which is a UV-curable PFPE hydrophobic compound, for example, or similar UV-curable hydrophobic PFPE. The PFPE hydrophobic compound can then be imprinted into (e.g., pressed further into) the wells of the nanowell array master using a transparent substrate (e.g., polyethylene terephthalate (PET) sheet or other substrates).

After applied and imprinted into the nanowell array master, the PFPE can be cured by UV light under pressure applied top-down on the transparent substrate. For example, the PFPE can be cured by UV light for 3 minutes under 2 bar of pressure applied top-down on the transparent substrate. This can be followed by another round of UV curing for 3 minutes under a vacuum and a post-annealing step at 100° C. for 45 minutes, or other periods of time, to the extent needed. Other curing or cross-linking approaches can be relied upon. The transparent substrate can be used to lift off (i.e., separate) the nanopillar array mold from the nanowell array master.

A cross-sectional view of a representative hydrophobic nanopillar array mold 400, as formed in step 302, is illustrated in FIG. 4A. The nanopillar array mold 400 is representative and not drawn to scale. The nanopillar array mold 400 is also shown with a PET sheet 410 and a carrier substrate 420. The PET sheet 410 can be used to lift the nanopillar array mold 400 off of the nanowell array master (not shown). FIG. 4A illustrates only a portion of the nanopillar array mold 400, in cross section. The nanopillar array mold 400 includes a number of nanopillars 401-403, among others, in an array of nanopillars. The nanopillars 401-403 are formed at a pitch “Pnp,” have a diameter “Dnp,” and have a length “Lpn.” The pitch “Pnp,” diameter “Dnp,” and length “Lnp” are determined by the pitch, diameter, and depth dimensions of the nanowells in the nanowell array master, as described above.

Referring back to FIG. 3, at step 304, the process includes forming a nanowell array using the nanopillar array mold 400 formed at step 302. The nanowell array can be a solvent-soluble nanowell array formed from poly(methyl methacrylate) (PMMA) in one example, although other types of materials can be used. As one example, a 16% weight for weight (w/w) solution of PMMA in anisole can be prepared and spin-coated on and over the nanopillar array mold 400. The PMMA can have an average molecular weight of 15,000 grams per mole (g/mol), although other types of PMMA can be used. The PMMA can be product number 200336 (CAS number 9011-14-7) of SIGMA-ALDRICH®, as one example. The anisole, exhibiting a low surface tension, can wet the hydrophobic PFPE nanopillar array mold, allowing conformal coating of the PMMA solution over the nanostructured PFPE surface of the nanopillar array mold. After sufficient mixing of the PMMA solution, it can be spin coated on and over the nanopillar array mold 400 at 5000 rpm, for 30 seconds, for example, followed by heating at 150° C. for 3 minutes to evaporate the anisole solvent. The thickness of PMMA can be optimized by controlling the spin-coating parameters, to ensure that PMMA layer does not extent above the length “Lnp” of the nanopillars 401-403 of the nanopillar array mold 400.

FIG. 4B illustrates a cross-sectional view of a PMMA solution 430 being applied and spin coated over the nanopillar array mold 400, and FIG. 4C illustrates a cross-sectional view of a nanowell array 432 over the nanopillar array mold 400. The nanowell array 432 is formed from solvent-soluble PMMA and results from the evaporation of the anisole solvent from the PMMA solution 430. The individual wells in the nanowell array 432 have dimensions that correspond to the dimensions of the of the nanowells in the nanowell array master, as described above. As shown in FIG. 4C, the nanowell array 432 covers and extends over the top surfaces of the nanopillars 401-403. Preferably, the regions of the nanowell array 432 that extend over the top surfaces of the nanopillars 401-403 are very thin and, in some cases, can be made as thin as practical by spin coating the PMMA solution 430.

The nanowell array forms a type of template for a nanoantenna array. As described below, a nanoantenna can be formed within the area bounded by each well in the nanowell array. The nanowell array 432 can be transferred to other surfaces or structures using the RNIL approach described below. Among various embodiments, the nanowell array 423 can be transferred to a range of different surfaces or structures. Example surfaces or structures upon which the nanowell array 423 can be transferred include flexible membranes, flexible polymeric sheets, flexible polymeric meshes, polymeric meshes, membranes, fabricated structures including electrodes, coated glass, and other surfaces. The nanowell array 423 can also be transferred to textiles and other flexible structures or materials in some cases. As particular examples, the nanowell array 423 can be transferred to the flexible scaffold 120 shown in FIG. 1A or to the micropillars 230-233 shown in FIG. 1B.

The surfaces or structures upon which the nanowell array 423 can be transferred should be separately fabricated or otherwise prepared, as needed. Examples of the separate fabrication of surfaces or structures upon which the nanowell array 423 can be transferred are described below with reference to steps 320, 322, and 324 in FIG. 3.

At step 320 in FIG. 3, the process can include forming a microwell mesh scaffold. The microwell mesh scaffold is one example of a structure upon which the nanowell array 423 can be transferred using the RNIL approach described herein. To form the microwell mesh scaffold, a layer of omnicoat can be spin-coated on a substrate, such as a silicon wafer, or another suitable carrier. The omnicoat can be spin-coated at 3000 rpm for 30 seconds, for example, followed by baking at 200° C. for 1 minute. An omnicoat of KAYAKU® Advanced Materials of Westborough, Massachusetts, can be relied upon, as one example, although other types or brands of omnicoat can be relied upon.

After the layer of omnicoat is prepared over the substrate, a photoresist layer can be formed over the layer of omnicoat as part of step 320. The photoresist layer can be patterned using lithography to include a number of microwells, forming a microwell mesh. As one example, a layer of the negative-tone SU8-2002 photoresist of KAYAKU® Advanced Materials can be formed over the layer of omicoat and patterned using lithography to include microwells. An SU8-2000.5 photoresist or other suitable photoresist can also be relied upon. The photoresist layer with microwells forms a microwell mesh scaffold. Many photoresist materials, including the SU8-2002 and SU8-2000.5 photoresists, are polymeric and flexible. Such photoresist materials can also be transparent to some extent. Such materials are also biocompatible for testing a range of biological activities and cellular interactions.

FIG. 4C illustrates a cross-sectional view of a microwell mesh scaffold 520 formed over a substrate or carrier 500, with a sacrificial layer of omnicoat 510 between the carrier 500 and the microwell mesh scaffold 520. The microwell mesh scaffold 520 is formed from photoresist, as described above, and can be flexible and transparent. The photoresist can be spin coated over the layer of omnicoat 510, soft baked, and otherwise pre-processed for photolithography according to the recommended processing specifications for the photoresist. The resulting photoresist layer can then be patterned into the microwell mesh scaffold 520 by selective exposure to UV light and developed. The microwell mesh scaffold 520 includes a well 522, among others. Although not shown in FIG. 4D, the microwell mesh scaffold 520 can include an array wells including the well 522. The shape and size of the well 522, among other wells, can correspond to the examples of the micropores 130-133 described above in FIG. 1A. The shape of the well 522 can also correspond to the examples of the wells or pores described above in FIG. 1C.

In the example shown, the well 522 has a width “Ww” and a height “Wh.” The width “Ww” of the well 522 can be sized in the micrometer range, such as between 1-100 μm, including all the widths between 1 μm and 100 μm in increments of 1 μm (e.g., 1 μm, 2 μm, 3 μm, . . . 99 μm, and 100 μm), although some smaller and larger pore sizes can be used in some cases. The height “Wh” of the well 522 can range from between 500 mm to 3500 mm. Example heights “Wh” of the well 522 include 1 μm, 2 μm, and 3 μm, although other heights can be relied upon. As measured from the centers of any two wells, the wells in the microwell mesh scaffold 520 can be spaced at a periodicity or pitch of between 3-1000 μm, including all the pitch spacings between 3 μm and 1000 μm in increments of 1 μm, although other pitches be used.

As noted above, the microwell mesh scaffold 520 is one example of a structure upon which the nanowell array 423 can be transferred using the RNIL approach described herein. Using the microwell mesh scaffold 520, a BTNMM similar to the BTNMM 100 shown in FIG. 1A can be formed. Alternatively, the nanowell array 423 can be transferred onto a micropillar array. In that case, an NLPNA array can be formed on micropillar structures, similar to the NLPNA micropillar array 200 shown in FIG. 1B. In other cases, the nanowell array 423 can be transferred onto other structures or surfaces.

At step 322 in FIG. 3, the process can include forming a micropillar array. The micropillar array is another example of a structure upon which the nanowell array 423 can be transferred using the RNIL approach described herein. To form the micropillar array, a photoresist can be spin coated over a substrate or carrier, soft baked, and otherwise pre-processed for photolithography according to the recommended processing specifications for the photoresist. The resulting photoresist layer can then be patterned into a micropillar array by selective exposure to UV light and developed. The micropillar array can include an array of micropillars. The size of the micropillars can range in various embodiments. The width of each pillar can be sized in the micrometer range, such as between 1-100 μm, including all the widths between 1 μm and 100 μm in increments of 1 μm (e.g., 1 μm, 2 μm, 3 μm, . . . 99 μm, and 100 μm), although smaller and larger pillar sizes can be used in some cases. The height of each pillar 522 can range from between 500 mm to 3500 mm. Example heights of the pillars include 1 μm, 2 μm, and 3 μm, although other heights can be relied upon. As measured from the centers of any two pillars, the pillars in the micropillar array can be spaced at a periodicity or pitch of between 3-1000 μm, including all the pitch spacings between 3 μm and 1000 μm in increments of 1 μm, although other pitches be used. The micropillars can also be formed in any suitable shape, including shapes described above in FIG. 1C.

At step 324 in FIG. 3, the process can include preparing another type of surface or structure 325 upon which the nanowell array 423 can be transferred using RNIL. For example, step 324 can include preparing a conductive indium tin oxide (ITO) coated glass or glass slide. Step 324 can include preparing a microporous, microwell mesh platform or scaffold, similar to that described above at step 320, and then forming an array of interdigitated electrodes (IDEs) on the microwell mesh platform using photolithography and electron beam evaporation. Such a platform with IDEs can allow bio-interfaced measurements using both electrochemical impedance spectroscopy (EIS) and SERS, enabling high-order bio-interfaced sensing in complex multicellular systems. As other examples, step 324 can include preparing a poly(acrylic acid) (PAA) sheet, a polyethylene terephthalate (PET) sheet, a textile, a membrane, or other structures or surfaces. Any and all of the above examples may be used as a surface or structure, referenced as the surface or structure 325 in FIG. 3, upon which the nanowell array 423 can be transferred using RNIL.

After the nanowell array 423 is formed at step 304 and the surface or structure upon which the nanowell array 423 is to be transferred is formed at one of steps 320, 322, or 324, the nanowell array 423 can be transferred to the surface or structure using RNIL at step 306. Particularly, at step 306, the process includes transferring the nanowell array. Step 306 can include transferring the nanowell array to a surface of the microwell mesh formed at step 320, transferring the nanowell array to the micropillar array formed at step 322, or transferring the nanowell array to the other surface or structure formed at step 324.

In one example, step 306 can include transferring the nanowell array to the microwell mesh using an RNIL approach. As shown in FIG. 4E, the nanowell array 432, nanopillar array mold 400, and PET sheet 410 can be flipped or turned over (e.g., reversed) and placed upon the top surface of the microwell mesh scaffold 520. The nanowell array 432 can be imprinted or otherwise adhered to the top surface of the microwell mesh scaffold 520 at pressure and temperature, as part of the RNIL transfer approach. The nanowell array 432 can be imprinted or adhered to the top surface of the microwell mesh scaffold 520 at a pressure of 2 bar and a temperature of 170° C. for a time of 10 minutes, as one example. Other imprint times, pressures, and temperatures (e.g., temperatures above the glass transition temperature of PMMA) can be used to adhere the nanowell array 432 to the microwell mesh scaffold 520. In this process, the nanowell array 432 is adhered sufficiently to the top surface of the microwell mesh scaffold 520. However, the nanowell array 432 cannot adhere to the top surface of the microwell mesh scaffold 520 in the region over the well 522 and other wells in the microwell mesh scaffold 520.

The PET sheet 410 and nanopillar array mold 400 can then be lifted off of and separated from the nanowell array 432. The low surface energy of PFPE facilitates the RNIL process by allowing easy detachment of the PFPE nanopillar array mold 400 from the imprinted PMMA nanowell array 432. At the same time, the high elastic modulus of PFPE with good mechanical stability at high temperatures prevents buckling of the PFPE nanopillars of the nanopillar array mold 400 at high temperatures during the RNIL process.

Over the regions where the nanowell array 432 adhered to the microwell mesh scaffold 520 during RNIL, the hydrophobic properties of the nanopillar array mold 400 permit release of the nanopillar array mold 400 from the nanowell array 432. That is, the nanowell array 432 remains positioned on and adhered to the top surface of the microwell mesh scaffold 520 when the nanopillar array mold 400 is separated from or lifted off of the nanowell array 432. On the other hand, over the regions where the nanowell array 432 is not adhered to the microwell mesh scaffold 520, such as over the well 522 and other wells in the microwell mesh scaffold 520, the nanowell array 432 is not separated from the nanopillar array mold 400. Instead, regions or areas of the nanowell array 432 that were positioned over the wells of the microwell mesh scaffold 520 are separated (i.e., torn away) from the remainder of the nanowell array 432, as the nanopillar array mold 400 is lifted off from the nanowell array 432.

FIG. 4F illustrates a cross-sectional view of the nanowell array 432 transferred to the microwell mesh scaffold 520, after step 306. As shown in FIG. 4F, the nanowell array 432 is adhered to the top surface of the microwell mesh scaffold 520. An opening is formed in the nanowell array 432 over the well 522 of the microwell mesh scaffold 520. The nanowell array 432 includes nanowells 433-438, among others. Relatively thin or small amounts of PMMA material can remain at the bottom of each of the nanowells 433-438, and an example region of PMMA 436A is referenced at the bottom of the nanowells 436 in FIG. 4F.

At step 308, the process includes etching the nanowell array to form nanohole openings through the nanowell array, effectively turning the nanowell array into a nanohole array. For example, a reactive-ion etching (RIE) process step can be used to form nanohole openings through the nanowell array in a plasma chamber. RIE can be performed in a plasma of molecular oxygen (O₂) under radio frequency (RF) power of 30 W, for example, for removing the residual PMMA at the bottom of the nanowells in the nanowell array. An RIE etch time of between 30 seconds to 90 seconds may be relied upon. In practice, the size of the resulting nanohole openings can be tuned or tailored based on both the dimensions of the original nanowells in the nanowell array and by the RIE etch time and process technique used to further open the nanowells into nanoholes. As one example, RIE was used to expand an initial nanohole diameter from about 150 nm to about 250 nm by increasing the RIE time from 0 seconds to 60 seconds, and other etch times can be relied upon.

As an example result of step 308, FIG. 4G illustrates a cross-sectional view of nanoholes 433H-438H over the microwell mesh scaffold 520. As compared to FIG. 4F, each of the nanowells 433-438 has been further opened into nanoholes 436H-438H, respectively. Each of the nanoholes 433H-438H is a complete opening or aperture through the PMMA material of the nanowell array 432, resulting in a nanohole array 432H. At the bottom of each nanohole 433H-438H, a nanoregion of the microwell mesh scaffold 520 is open and exposed. Step 308 can also be performed using the micropillar array formed at step 322 and the other surfaces or structures formed at step 324.

At step 310, the process includes depositing alternating metal and insulating layers over the nanohole array and into the nanoholes. The deposition of the alternating metal and insulating layers forms an NLPNA array. The metal and insulating layers can be formed as a stack of thin films by EBPVD or other suitable materials deposition processing techniques, as described above with reference to FIG. 1C. The thicknesses of the metal and insulating layers can be selected to achieve multi-resonant plasmonic responses across a broad visible to near-infrared (Vis-NIR) range.

Referring to FIG. 4H, the stack of alternating metal and insulating layers is deposited over and on the top surface of the nanohole array 432H. The stack is also deposited within the nanoholes 433H-438H of the nanohole array 432H. Within the nanoholes 433H-438H, the stack is deposited upon the top surface of the microwell mesh scaffold 520. The stacks of metal and insulating layers are separated from each other in each of the nanoholes 433H-438H. The materials stacks are representative and not drawn to scale or size in FIG. 4H.

An example materials stack 600 is referenced on the top surface of the microwell mesh scaffold 520 within the nanohole 436H, and a similar materials stack is also positioned on the top surface of the microwell mesh scaffold 520 within each of the nanoholes 433H-435H, 437H, and 438H. The materials stack 600 is similar to the materials stack 150 shown in FIG. 1C, as an example, and forms a nanoantenna. The alternating metal and insulating layers that are deposited on the top surface of the microwell mesh scaffold 520, each of which forms a separate nanoantenna, forms NLPNA array on the microwell mesh scaffold 520.

At step 312 in FIG. 3, the process includes dissolving the nanohole array in a solvent, such as anisole or water. For example, the structure shown in FIG. 4H can be submerged in anisole or water, or such a solvent can be otherwise poured or spread over the structure. The solvent softens the nanohole array 432H. The solvent also weakens the adhesion between the nanohole array 432H and the microwell mesh scaffold 520, to permit reliable release of the nanohole array 432H from the top surface of the microwell mesh scaffold 520. The nanohole array 432H can be softened until it can be lifted off and separated from the microwell mesh scaffold 520.

An example result of step 312 is shown in FIG. 4I. In FIG. 4I, the nanohole array 432H has been lifted off and separated from the microwell mesh scaffold 520. An NLPNA array 610 remains on the top surface of the microwell mesh scaffold 520. The NLPNA array 610 includes an array of nanoantennas. Each nanoantenna in the NLPNA array 610 is formed from a stack of alternating metal and insulating layers.

At step 314, the process includes etching the nanoantenna array to expose plasmonic nanogap hotspots of the array. As an example, reactive ion etching (RIE) in a plasma of molecular O₂ can be used to remove any residual solvent that may remain on the NLPNA array 610 from step 312. The RIE etching time be tailored for SERS sensitivity or the sensitivity other plasmonic modes or enhancement techniques in some cases. Step 314 can also include etching the nanoantenna array with a wet etchant in some cases. For example, an etching solution including a buffered oxide etch (BOE) of hydrogen fluoride (HF) and ammonium fluoride (NH₄F) can be mixed with water (e.g., a 10:1 solution of BOE and water) and be applied to the NLPNA array 610. The etching solution can partially etch the dielectric layers in the NLPNA array 610 and open plasmonic nanogap hotspots in the NLPNA array 610.

At step 316, the process includes releasing the nanoantenna array. For example, the layer of omnicoat 510 between the carrier 500 and the microwell mesh scaffold 520 can be developed using a developer, such as Microposit MF-319 of KAYAKU® Advanced Materials, to release the microwell mesh scaffold 520 and the NLPNA array 610 from the carrier 500. Step 316 can also include rinsing the microwell mesh scaffold 520 and the NLPNA array 610 in deionized water. The microwell mesh scaffold 520 and the NLPNA array 610 can be rinsed in deionized water any number of times, such as once, twice, three times or more, with new deionized water.

The BTNMM devices, NLPNA arrays, and related structures described herein can be used in optical sensing, microscopy, optical communications, bio-photonics, and other fields. Compared to other methods using freestanding metal nanohole arrays as physical deposition masks, the methods described herein offer several unique advantages. The advantages include higher throughput and reduced cost of generating nanohole array deposition masks by polymeric molding with reusable PFPE nanopillar molds. The advantages also include facile transfer of the nanohole array masks onto a variety of micro/nanostructured surfaces via RNIL, the generation of uniformly-shaped multilayered nanodisks over large areas via line-of-sight deposition due to the continuous and conformal contact between the nanohole array masks and the micro/nanostructured surfaces, and easy tunability of the diameter of the nanoholes via RIE.

The features, structures, or characteristics described above may be combined in one or more embodiments in any suitable manner, and the features discussed in the various embodiments are interchangeable, if possible. In the foregoing description, numerous specific details are provided in order to fully understand the embodiments of the present disclosure. However, a person skilled in the art will appreciate that the technical solution of the present disclosure may be practiced without one or more of the specific details, or other methods, components, materials, and the like may be employed. In other instances, well-known structures, materials, or operations are not shown or described in detail to avoid obscuring aspects of the present disclosure.

Although relative terms such as “above,” “below,” “upper,” “lower,” “top,” “bottom,” “right,” “left,” “input,” and “output” may be used to describe the relative spatial relationships of certain components or structural features, the terms are used for convenience in the examples. It should be understood that if a device or component is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. are used as distinguishing labels in some cases, rather than a limitation of the number of the objects, unless otherwise specified.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A method of manufacture of a plasmonic nanoantenna array, comprising:
forming a nanowell array;
transferring the nanowell array to a surface using reverse nanoimprint lithography;
etching the nanowell array to form a nanohole array comprising nanoholes that expose openings on the surface;
depositing alternating metal and insulating layers into the nanoholes and onto the openings on the surface, to form a nanoantenna array on the surface; and
dissolving the nanohole array.

2. The method of claim 1, wherein depositing the alternating metal and insulating layers comprises depositing alternating layers of gold and silicon dioxide.

3. The method of claim 1, wherein forming the nanowell array comprises:
forming a nanowell array master;
forming a nanopillar array mold using the nanowell array master; and
forming the nanowell array using the nanopillar array mold.

4. The method of claim 1, wherein forming the nanowell array comprises:
forming a nanowell array master in silicon;
forming a nanopillar array mold from perfluoropolyether (PFPE) using the nanowell array master; and
forming the nanowell array from poly(methyl methacrylate) (PMMA) using the nanowell array master.

5. The method of claim 4, wherein forming the nanowell array comprises:
preparing a solution of PMMA in a solvent;
spin coating the solution of PMMA over the nanopillar array mold; and
heating the solution of PMMA to evaporate the solvent.

6. The method of claim 1, wherein etching the nanowell array comprises reactive ion etching (RIE) the nanowell array in a plasma of oxygen.

7. The method of claim 1, wherein the surface comprises a top surface of a microwell mesh, the microwell mesh comprising a plurality of microwells.

8. The method of claim 7, wherein the microwell mesh comprises a transparent, polymeric microwell mesh.

9. The method of claim 1, wherein the surface comprises top surfaces of micropillars in a micropillar array.

10. The method of claim 1, wherein the surface comprises a top surface of a coated glass.

11. The method of claim 1, wherein the surface comprises an array of interdigitated electrodes.

12. The method of claim 1, wherein the surface comprises an array of interdigitated electrodes on a microwell mesh.

13. A method of manufacture of a biomimetic transparent nanoplasmonic mesh, comprising:
forming a nanowell array master in a silicon substrate;
forming a hydrophobic nanopillar array mold from hydrophobic perfluoropolyether (PFPE) using the nanowell array master;
forming a solvent-soluble nanowell array from poly(methyl methacrylate) (PMMA) using the hydrophobic nanopillar array mold;
forming a microwell mesh over a carrier substrate;
transferring the nanowell array to a surface of the microwell mesh using reverse nanoimprint lithography;
etching the nanowell array to form a nanohole array comprising nanoholes that expose openings on the surface of the microwell mesh;
depositing alternating metal and insulating layers over the nanohole array and onto the openings on the surface of the microwell mesh, to form a nanoantenna array on the surface; and
dissolving the nanowell array; and
releasing the microwell mesh and the nanoantenna array from the carrier substrate.

14. The method of claim 13, wherein depositing the alternating metal and insulating layers comprises depositing alternating layers of gold and silicon dioxide.

15. The method of claim 13, wherein forming the nanowell array comprises:
preparing a solution of PMMA in a solvent;
spin coating the solution of PMMA over the nanopillar array mold; and
heating the solution of PMMA to evaporate the solvent.

16. The method of claim 13, wherein etching the nanowell array comprises reactive ion etching (RIE) the nanowell array in a plasma of oxygen.

17. The method of claim 13, wherein the microwell mesh comprises a plurality of microwells.

18. The method of claim 13, wherein the microwell mesh comprises a transparent, polymeric microwell mesh.

19. A biomimetic transparent nanoplasmonic mesh, comprising:
a flexible, transparent microwell mesh comprising a plurality of microwells; and
a nanoantenna array on a surface of the microwell mesh.

20. The nanoplasmonic mesh of claim 19, wherein each nanoantenna in the nanoantenna array comprises alternating metal and insulating layers of metal and an insulator.
